(19) United States
(12) Patent Application Publication
(10) Pub. No.: US 2021/0335924 A1
(43) Pub. Date: Oct. 28, 2021

(54) DISPLAY PANEL, PREPARATION METHOD THEREOF, AND DISPLAY DEVICE

(71) Applicant: WUHAN CHINA STAR OPTOELECTRONICS SEMICONDUCTOR DISPLAY TECHNOLOGY CO., LTD., Wuhan, Hubei (CN)

(72) Inventor: Sihang BAI, Wuhan, Hubei (CN)

(21) Appl. No.: 16/613,669

(22) PCT Filed: Oct. 21, 2019
(86) PCT No.: PCT/CN2019/112227

§ 371 Date: Nov. 14, 2019

(30) Foreign Application Priority Data
Jul. 16, 2019 (CN) 201910639535.6

(51) Int. Cl. H01L 27/32; H01L 51/52; H01L 51/56

(52) U.S. Cl. CPC H01L 27/3244; H01L 27/3234; H01L 27/323; H01L 2227/323; H01L 51/5237; H01L 51/56; H01L 51/5293

(57) ABSTRACT

The invention discloses a display panel, a preparation method thereof, and a display device. The display panel includes a substrate, a flexible layer, and a thin film transistor layer. A portion of the flexible layer corresponding to the image capturing area is transparent. The thin film transistor layer includes: a plurality of first thin film transistor units disposed within the image capturing area and a plurality of second thin film transistor units disposed within the non-image capturing area, a density of the first thin film transistor units is less than that of the second thin film transistor units.

### FIELD OF INVENTION

The present invention relates to the field of display, and in particular, to a display panel, a method for preparing the same, and a display device.

### BACKGROUND OF INVENTION

Full-screen technology is a relatively broad definition of an ultra-high screen ratio mobile phone design in the display industry. Literally, an entire area of the front side of the mobile phone is all screen, the display interface of the mobile phone is completely covered by the screen, and four sides of the mobile phone are designed to have no borders and striving to reach a nearly 100% ultra-high screen ratio. However, limited by the basic functional requirements that are indispensable for mobile phones such as front camera, earpiece, distance sensor, and light sensor, etc., there is a notch in the top of the screen of the mobile phone to accommodate the above-mentioned functional components. The full-screen mobile phone claimed by the industry is currently only an ultra-high screen ratio mobile phone, and does not reach a 100% screen ratio, which is called “screen with bangs”. With the ultra-narrow bezel design, its real screen ratio (unofficial publicity) can reach 80-90%, and there is still a way to go to obtaining a 100% full screen.

In order to realize the narrow bezel design of small-sized mobile phone and achieve a larger screen ratio of the mobile phone, the industry has tried to reduce the bonding area. The most effective way to reduce a lower boundary is so-called side bonding technology, which bends part of a fan-out area of a screen, the driver IC, and the flexible circuit board together to a back of the screen for bonding, which can effectively reduce a length of the lower bonding area. However, the front camera is usually disposed in the upper bonding area, for further reducing the upper boundary, the industry adopts the “screen with bangs” or “water droplet screen” to reduce the boundary and increase the screen ratio.

No matter what the design is, a camera is disposed in the non-display area under the screen. In order to achieve a true full screen and improve the customer's visual experience, we need to combine the camera into the display area, that is, the camera can be normally used to photograph and the light transmittance is high, and the screen can be normally displayed when photographing function is not used.

### Technical Problem

In order to solve the above technical problem, the invention provides a display panel, a preparation method thereof, and a display device, so as to solve the technical problem in the prior art that the camera is always disposed within the non-display area.

### SUMMARY OF INVENTION

The present invention provides a display panel, a method for preparing the same, and a display device for solving the problem that in order to ensure the light transmittance of the image capturing area, a true “full screen” cannot be achieved.

The technical solution to solve the above problem is that the invention provides a display panel, including: an image capturing area and a non-image capturing area surrounding the image capturing area; the display panel includes: a substrate; a flexible layer disposed on the substrate, wherein a portion of the flexible layer corresponding to the image capturing area is transparent; a thin film transistor layer disposed on the flexible layer, wherein the thin film transistor layer includes: a plurality of first thin film transistor units disposed within the image capturing area and a plurality of second thin film transistor units disposed within the non-image capturing area, a density of the first thin film transistor units is less than a density of the second thin film transistor units.

Further, material of the flexible layer includes polyimide, and the portion of the flexible layer corresponding to the image capturing area is made of a transparent polyimide material.

Further, a density ratio of the first thin film transistor unit to the second thin film transistor unit is between 1:2 and 1:30.

Further, the display panel further including: an organic light-emitting layer disposed on the thin film transistor layer; an encapsulation layer disposed on the organic light-emitting layer; a touch layer disposed on the encapsulation layer; and an optical film structure layer disposed on the touch layer.

Further, the optical film structure layer includes: a polarizer layer disposed on the touch layer, and the polarizer layer is provided with a light transmission hole corresponding to the image capturing area; an optical adhesive disposed on a side of the polarizer layer away from the touch layer; and a protective layer disposed on a side of the optical adhesive away from the polarizer layer.

The invention also provides a preparation method of a display panel, the display panel including an image capturing area and a non-image capturing area surrounding the image capturing area, wherein the method includes: providing a substrate; forming a flexible layer by depositing on the substrate, wherein a portion of the substrate corresponding to the image capturing area is deposited with transparent flexible material; forming a thin film transistor layer on the flexible layer; defining a first thin film transistor area within the image capturing area, and forming a plurality of evenly arranged first thin film transistor units within the first thin film transistor area; defining a second thin film transistor area within the non-image capturing area, and forming a plurality of evenly arranged second thin film transistor units within the second thin film transistor area; wherein a density of the second thin film transistor units corresponding to the non-image capturing area is less than a density of the first thin film transistor units corresponding to the image capturing area.

Further, the material for forming the flexible layer is a polyimide material, and wherein a portion of the flexible layer corresponding to the image capturing area is made of a transparent polyimide material.

Further, the method of preparing the display panel further including: forming an encapsulation layer on the thin film transistor layer; forming a touch layer on the encapsulation layer; and forming an optical film structure layer on the touch layer.

Further, the optical film structure layer includes a polarizer layer, and a light-transmitting hole is provided in the polarizer layer corresponding to the image capturing area.

The present invention also provides a display device including the display panel.

### BENEFICIAL EFFECT

The display panel, the preparation method thereof, and the display device of the present invention adopt two solutions to improve light transmittance of the image capturing area. First, replace a yellow flexible layer of the image capturing area with a transparent polyimide (PI). Second, reducing a pixel density (pixels per inch, PPI) of the image capturing area, adopting a sparse array to improve light transmission in the premise of not affecting the display effect. The polarizer still adopts a way of creating an opening in the image capturing area to increase the light transmittance.

### DESCRIPTION OF DRAWINGS

In order to more clearly illustrate the technical solutions in the embodiments of the present invention, the drawings used in the embodiments will be briefly described below. It is obvious that the drawings in the following description are only some embodiments of the present invention. Other drawings can also be obtained by those skilled in the art based on these drawings without doing any creative effort.

FIG. 1 is a schematic view of a display panel in embodiment 1.

FIG. 2 is a schematic view of a display panel in embodiment 2.

FIG. 3 is a schematic view of a display panel in embodiment 3.

FIG. 4 is a distribution diagram of thin film transistor units in embodiment 2.

FIG. 5 is a plan view of the display panel in embodiment 3.

FIG. 6 is a schematic view showing a structural layer of an optical film in embodiment 3.

FIG. 7 is a schematic view showing a display device in embodiment 3.

### REFERENCE NUMERALS

1 display device; 10 display panel; 110 substrate; 120 flexible layer; 101 image capturing area; 102 non-image capturing area; 1201 transparent polyimide film; 130 thin film transistor layer; 131 first thin film transistor area; 132 second thin film transistor area; 1311 first thin film transistor unit; 1321 second thin film transistor unit; 140 organic light-emitting layer; 150 encapsulation layer; 160 touch layer; 170 optical film structure layer; 1411 first shielding area; 1412 first light transmission area; 1421 second shielding area; 1422 second light transmission area; 171 light transmission hole.

### DETAILED DESCRIPTION OF PREFERRED EMBODIMENTS

The following description of the embodiments specific embodiments is provided to illustrate the specific embodiments of the invention. The directional terms mentioned in the present invention, such as “upper”, “lower”, “front”, “back”, “left”, “right”, “top”, “bottom”, etc., are only referred to a direction of the drawings. Therefore, the directional terminology used is for the purpose of illustration and understanding of the invention rather than limiting the invention.

### Embodiment 1

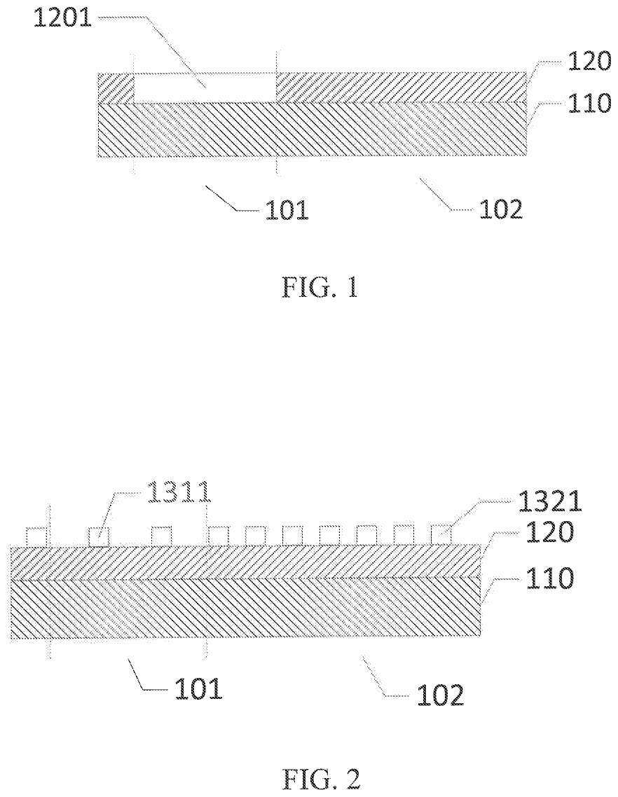

As shown in FIG. 1, in the embodiment, the display panel 10 includes a substrate 110 and a flexible layer 120.

The display panel 10 includes an image capturing area 101 and a non-image capturing area 102 surrounding the image capturing area 101, and the image capturing area 101 is used to dispose a camera. When the camera is capturing images, external light enters the camera via the image capturing area 101 and the images are processed by the internal processor to form a photo or video. In order to ensure the quality of the photo or the video, while avoiding the “droplet screen”, “screen with bangs” and the like design in the prior art which affects the screen ratio of the display panel 10, it is necessary to increase the light transmission of the image capturing area 101.

The flexible layer 120 is disposed on the substrate 110. In the prior art, the material of the flexible layer 120 is a polyimide, which is a thin film insulating material with good performance, generally a yellow transparent film.

The portion of the flexible layer 120 corresponding to the image capturing area 101 is a transparent flexible layer 1201, which can not only achieve the technical effect of insulation but also increase the light transmittance of the image capturing area 101.

### Embodiment 2

As shown in FIG. 2, in the present embodiment, the display panel 10 of the present invention includes a substrate 110, a flexible layer 120, and a thin film transistor layer 130.

The display panel 10 includes an image capturing area 101 and a non-image capturing area 102 surrounding the image capturing area 101, and the image capturing area 101 is used to dispose a camera. When the camera is capturing images, external light enters the camera via the image capturing area 101 and the images are processed by the internal processor to form a photo or video. In order to ensure the quality of the photo or the video, while avoiding the “droplet screen”, “screen with bangs” and the like designs in the prior art which affects the screen ratio of the display panel 10, it is necessary to increase the light transmission of the image capturing area 101.

As shown in FIG. 4, the thin film transistor layer 130 is disposed on the flexible layer 120. The thin film transistor layer 130 is composed of a plurality of thin film transistor units, consequently, the thin film transistors play an important role for the light transmittance. In the embodiment, the thin film transistor layer 130 is divided into a first thin film transistor area 131 and a second thin film transistor area 132, wherein the first thin film transistor area 131 corresponds to the image capturing area 101, and a plurality of first thin film transistor units 1311 are evenly distributed in the first thin film transistor area 131. Gaps between the first thin film transistor units 1311 is wider, generally, the size of the gap of the prior art thin film transistor units is between ½ and 1/30 of that of the present thin film transistor units. Specifically, it is 1/9 of the present thin film transistor units, consequently, facilitating light entering the camera through the gap between the first thin film transistor units 1311.

The second thin film transistor area 132 corresponds to the non-image capturing area 102, and a plurality of second thin film transistor units 1321 are evenly distributed in the second thin film transistor area 132. The gap between the second thin film transistor unit is a common design used in the industry, mainly to ensure the color gamut and brightness of the display panel 10.

### Embodiment 3

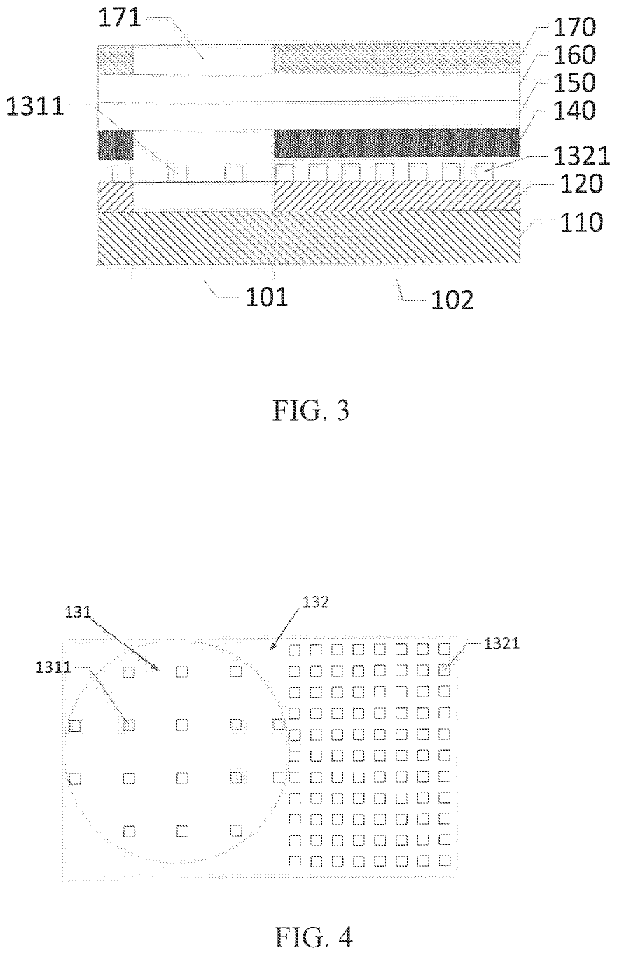

As shown in FIG. 3, in the embodiment, the display panel 10 of the present invention includes a substrate 110, a flexible layer 120, a thin film transistor layer 130, an organic light-emitting layer 140, an encapsulation layer 150, a touch layer 160, and an optical film structure layer 170.

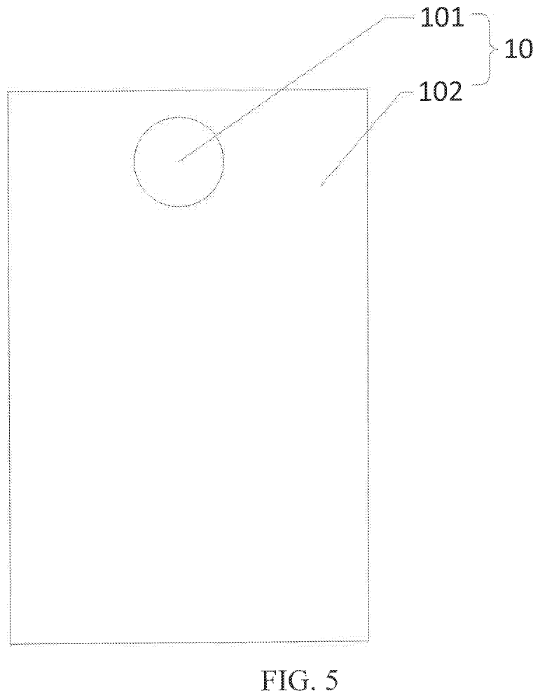

As shown in FIG. 5, the display panel 10 includes an image capturing area 101 and a non-image capturing area 102 surrounding the image capturing area 101, and the image capturing area 101 is used to dispose a camera. When the camera is capturing images, external light enters the camera via the image capturing area 101 and the images are processed by the internal processor to form a photo or video. In order to ensure the quality of the photo or the video, while avoiding the “droplet screen”, “screen with bangs” and the like design in the prior art which affects the screen ratio of the display panel 10, it is necessary to increase the light transmission of the image capturing area 101.

The flexible layer 120 is disposed on the substrate 110. The material of the flexible layer 120 is a polyimide film, which is a thin film insulating material with good performance, generally a yellow transparent film.

The portion of the flexible layer 120 corresponding to the image capturing area 101 is a transparent flexible layer 1201, which can not only achieve the technical effect of insulation but also increase the light transmittance of the image capturing area 101.

The thin film transistor layer 130 is disposed on the flexible layer 120. The thin film transistor layer 130 is composed of a plurality of thin film transistor units, consequently, the thin film transistors play an important role for the light transmittance. In the embodiment, the thin film transistor layer 130 is divided into a first thin film transistor area 131 and a second thin film transistor area 132, wherein the first thin film transistor area 131 corresponds to the image capturing area 101, and a plurality of first thin film transistor units 1311 are evenly distributed in the first thin film transistor area 131. Gaps between the first thin film transistor units 1311 is wider, generally, the size of the gap of the prior art thin film transistor units is between ½ and 1/30 of that of the present thin film transistor units. Specifically, it is 1/9 of the present thin film transistor units, consequently, facilitating light entering the camera through the gap between the first thin film transistor units 1311.

The second thin film transistor area 132 corresponds to the non-image capturing area 102, and a plurality of second thin film transistor units 1321 are evenly distributed in the second thin film transistor area 132. The gap between the second thin film transistor unit is a common design used in the industry, mainly to ensure the color gamut and color brightness of the display panel 10.

The organic light-emitting layer 140 is disposed on the thin film transistor layer 130. The organic light-emitting layer 140 includes a transparent electrode and a non-transparent electrode, wherein the non-transparent electrode and the transparent electrode are both disposed within the non-image capturing area 102.

The encapsulation layer 150 is disposed on the organic light-emitting layer 140, the touch layer 160 is disposed on the encapsulation layer 150, and the optical film structure layer 170 is disposed on the touch layer 160.

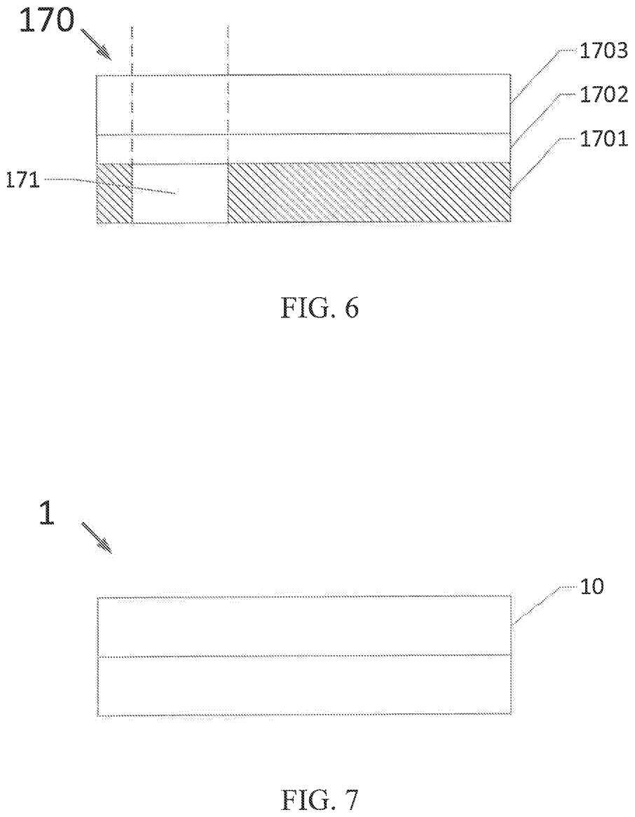

As shown in FIG. 6, the optical film structure layer 170 is provided with a light transmission hole 171 corresponding to the image capturing area 101. Specifically, the optical film structure layer 170 includes a polarizer layer 1701, an optical adhesive 1702, and a protective layer 1703, the polarizer layer 1701 is disposed on the touch layer 160. The light transmission hole 171 is disposed at a site of the image capturing area 101 corresponding to the polarizer layer for improving the light transmittance at the image capturing area 101.

The optical adhesive 1702 is disposed on a side of the polarizer layer 1701 away from the touch layer 160. The protective layer 1703 is disposed on a side of the optical adhesive 1702 away from the polarizer layer 1701 to protect the polarizer layer 1701 and prevent it from wearing out.

In order to better explain the present invention, in the embodiment, a method for preparing the display panel is further provided. The specific steps are as follows: providing a substrate 110; forming a flexible layer 120 by depositing on the substrate 110, wherein a transparent flexible layer 1201 is formed on the substrate corresponding to the image capturing area by depositing a transparent flexible layer material; forming a thin film transistor layer 130 on the flexible layer 120; defining a first thin film transistor area 131 within the image capturing area 101, and forming a plurality of evenly arranged first thin film transistor units 1311 within the first thin film transistor area 131; defining a second thin film transistor area 132 within the non-image capturing area 102, and forming a plurality of evenly arranged second thin film transistor units 1321 within the second thin film transistor area 132; wherein a density of the second thin film transistor units corresponding to the non-image capturing area 102 is less than a density of the first thin film transistor units corresponding to the image capturing area 101. The transmittance of the image capturing area 101 is improved by reducing the density of the first thin film transistor unit 1311, under the premise of ensuring the display quality of the display panel 10.

Following, forming an encapsulation layer 150 on the thin film transistor layer 130; forming a touch layer 160 on the encapsulation layer 150; and forming an optical film structure layer 170 on the touch layer 160, wherein the optical film structure layer includes a polarizer layer 1701, and a light-transmitting hole 171 is provided in the polarizer layer 1701 corresponding to the image capturing area 101.

As shown in FIG. 7, in the embodiment, the display device 1 of the present invention includes the display panel 10, and the display device 1 can be a mobile phone, a computer, a television, or the like.

The description of the above exemplary embodiments is only for the purpose of understanding the invention. It is to be understood that the present invention is not limited to the disclosed exemplary embodiments. It is obvious to those skilled in the art that the above exemplary embodiments may be modified without departing from the scope and spirit of the present invention.

What is claimed is:

1. A display panel, comprising: an image capturing area and a non-image capturing area surrounding the image capturing area, the display panel comprising:
a substrate;
a flexible layer disposed on the substrate, wherein a portion of the flexible layer corresponding to the image capturing area is transparent; and
a thin film transistor layer disposed on the flexible layer, wherein the thin film transistor layer comprises:
a plurality of first thin film transistor units disposed within the image capturing area and a plurality of second thin film transistor units disposed within the non-image capturing area, a density of the first thin film transistor units is less than a density of the second thin film transistor units.

2. The display panel according to claim 1, wherein material of the flexible layer comprises polyimide, and the portion of the flexible layer corresponding to the image capturing area is made of a transparent polyimide material.

3. The display panel according to claim 1, wherein a density ratio of the first thin film transistor unit to the second thin film transistor unit is between 1:2 and 1:30.

4. The display panel according to claim 1, further comprising:
an organic light-emitting layer disposed on the thin film transistor layer;
an encapsulation layer disposed on the organic light-emitting layer;
a touch layer disposed on the encapsulation layer; and
an optical film structure layer disposed on the touch layer.

5. The display panel according to claim 4, wherein the optical film structure layer comprises:
a polarizer layer disposed on the touch layer, and the polarizer layer is provided with a light transmission hole corresponding to the image capturing area;
an optical adhesive disposed on a side of the polarizer layer away from the touch layer; and
a protective layer disposed on a side of the optical adhesive away from the polarizer layer.

6. A method of preparing a display panel, the display panel comprising an image capturing area and a non-image capturing area surrounding the image capturing area, wherein the method comprises:
providing a substrate;
forming a flexible layer on the substrate, wherein a portion of the substrate corresponding to the image capturing area is deposited with transparent flexible material;
forming a thin film transistor layer on the flexible layer;
defining a first thin film transistor area within the image capturing area, and forming a plurality of evenly arranged first thin film transistor units within the first thin film transistor area;
defining a second thin film transistor area within the non-image capturing area, and forming a plurality of evenly arranged second thin film transistor units within the second thin film transistor area;
wherein a density of the second thin film transistor units corresponding to the non-image capturing area is less than a density of the first thin film transistor units corresponding to the image capturing area.

7. The method of preparing the display panel according to claim 6, wherein the material for forming the flexible layer is a polyimide material, and wherein a portion of the flexible layer corresponding to the image capturing area is made of a transparent polyimide material.

8. The method of preparing the display panel according to claim 6, further comprising:
forming an encapsulation layer on the thin film transistor layer;
forming a touch layer on the encapsulation layer; and
forming an optical film structure layer on the touch layer.

9. The method of preparing the display panel according to claim 8, wherein the optical film structure layer comprises a polarizer layer, and a light-transmitting hole is provided in the polarizer layer corresponding to the image capturing area.

10. A display device, comprising the display panel of claim 1.
